(19) United States
(12) Patent Application Publication
(10) Pub. No.: US 2025/0268064 A1
(43) Pub. Date: Aug. 21, 2025

(54) DISPLAY PANEL AND METHOD FOR MANUFACTURING DISPLAY PANEL, AND DISPLAY MODULE

(71) Applicants: Hefei Visionox Technology Co., Ltd., Hefei (CN); Visionox Technology Inc., Suzhou (CN)

(72) Inventors: Yuting FU, Hefei (CN); Yuan YAO, Hefei (CN); Wei-Ju HUANG, Hefei (CN); Yi-Yu LAI, Hefei (CN); Liping XU, Hefei (CN); Lipeng GAO, Hefei (CN)

(73) Assignees: Hefei Visionox Technology Co., Ltd., Hefei (CN); Visionox Technology Inc., Suzhou (CN)

(21) Appl. No.: 18/754,178

(22) Filed: Jun. 26, 2024

(30) Foreign Application Priority Data
Feb. 18, 2024 (CN) 202410181878.3

(51) Int. Cl. H10K 59/80; H10K 59/12

(52) U.S. Cl. CPC H10K 59/873; H10K 59/1201

(57) ABSTRACT

Disclosed are a display panel and a method for manufacturing the display panel, and a display module, solving a problem of low reliability of a display panel in a conventional technology. The display panel has a display area and an edge area surrounding the display area. The display panel includes: a substrate; a plurality of light-emitting devices; a dam, disposed on the substrate and located in the edge area; and an encapsulation structure, stacked on a side, facing away from the substrate, of the dam and the light-emitting device. The encapsulation structure includes a first inorganic encapsulation layer and a second inorganic encapsulation layer which are stacked with each other. The first inorganic encapsulation layer is located on a side, close to the substrate, of the second inorganic encapsulation layer. The second inorganic encapsulation layer extends from the display area to the edge area to directly contact with the dam.

### CROSS-REFERENCE TO RELATED APPLICATION

This application claims priority to Chinese Patent Application No. 202410181878.3, filed on Feb. 18, 2024, which is hereby incorporated by reference in its entirety.

### TECHNICAL FIELD

Embodiments of the present disclosure relate to the field of display technologies, and in particular, to a display panel and a method for manufacturing a display panel, and a display module.

### BACKGROUND

In recent years, with the rise of intelligent terminal products, the display panel industry has also developed rapidly. However, in a high-temperature and high-humidity environment, a film layer at an edge of encapsulation of the display panel is prone to peeling off, resulting in low product reliability.

### SUMMARY

In view of this, embodiments of the present disclosure provide a display panel and a method for manufacturing a display panel, and a display module to solve a problem of low reliability of a display panel in the conventional technology.

A first aspect of the present disclosure provides a display panel, having a display area and an edge area surrounding the display area. The display panel includes: a substrate; a plurality of light-emitting devices, disposed on the substrate and located in the display area; a dam, disposed on the substrate and located in the edge area, where the dam is disposed surrounding the display area; and an encapsulation structure, stacked on a side, facing away from the substrate, of the dam and the plurality of light-emitting devices. The encapsulation structure includes a first inorganic encapsulation layer and a second inorganic encapsulation layer which are stacked with each other. The first inorganic encapsulation layer is located on a side, close to the substrate, of the second inorganic encapsulation layer; and the second inorganic encapsulation layer extends from the display area to the edge area to directly contact with the dam.

A second aspect of the present disclosure further provides another display panel, having a display area and an edge area surrounding the display area. The display panel includes: a substrate; a plurality of light-emitting devices, disposed on the substrate and located in the display area; and an encapsulation structure, stacked on a side, facing away from the substrate, of the plurality of light-emitting devices. The encapsulation structure includes a first inorganic encapsulation layer and a second inorganic encapsulation layer which are stacked with each other. The first inorganic encapsulation layer is located on a side, close to the substrate, of the second inorganic encapsulation layer; and an orthographic projection of the first inorganic encapsulation layer on the substrate is located within an orthographic projection of the second inorganic encapsulation layer on the substrate.

A third aspect of the present disclosure provides a method for manufacturing a display panel, including: preparing a dam and a plurality of light-emitting devices on a substrate, where the dam surrounds the plurality of light-emitting devices; and preparing an encapsulation structure on a side, facing away from the substrate, of the plurality of light-emitting devices and the dam, to obtain the display panel, the encapsulation structure including a first inorganic encapsulation layer and a second inorganic encapsulation layer which are stacked with each other, the first inorganic encapsulation layer located on a side, away from the substrate, of the second inorganic encapsulation layer, and the second inorganic encapsulation layer directly contacting with the dam.

A fourth aspect of the present disclosure provides a display module, including the display panel provided in the first aspect or the second aspect.

According to the display panel and the method for manufacturing the display panel, and the display module provided by the embodiments of the present disclosure, an orthographic projection of a first inorganic encapsulation layer close to a substrate is located within an orthographic projection of an area defined by a dam, so that a contact surface between the dam and the encapsulation structure is actually a contact surface between the top film layer and the second inorganic encapsulation layer. Therefore, a quantity of interfaces at an encapsulation edge is reduced. Meanwhile, a thickness of film layers at the encapsulation edge is reduced, so that an interface bonding force is improved, a probability of separation at the interface between film layers in a high-temperature and high-humidity environment is reduced, and the reliability of the display panel is further improved.

### BRIEF DESCRIPTION OF THE DRAWINGS

FIG. 1 is a cross-sectional view of a display panel in related technologies.

FIG. 2 is a top view of a display panel according to an embodiment of the present disclosure.

FIG. 3 is a cross-sectional view of the display panel along line A1-A2 shown in FIG. 2.

FIG. 4a is a cross-sectional view of a display panel according to another embodiment of the present disclosure.

FIG. 4b is a top view of the display panel shown in FIG. 4a.

FIG. 5 is a cross-sectional view of a display panel according to still another embodiment of the present disclosure.

FIG. 6 is a cross-sectional view of a display panel according to yet still another embodiment of the present disclosure.

FIG. 7 is a cross-sectional view of a display panel according to yet still another embodiment of the present disclosure.

FIG. 8 is a cross-sectional view of a display panel according to yet still another embodiment of the present disclosure.

FIG. 9 is a cross-sectional view of a display panel according to yet still another embodiment of the present disclosure.

FIG. 10 is a flowchart of a method for manufacturing a display panel according to an embodiment of the present disclosure.

FIG. 11 is a flowchart of a method for manufacturing a display panel according to another embodiment of the present disclosure.

FIG. 12 is a flowchart of a method for manufacturing a display panel according to still another embodiment of the present disclosure.

FIG. 13 is a flowchart of a method for manufacturing a display panel according to yet still another embodiment of the present disclosure.

FIG. 14 is a schematic structural diagram of a display apparatus according to an embodiment of the present disclosure.

### DETAILED DESCRIPTION OF THE EMBODIMENTS

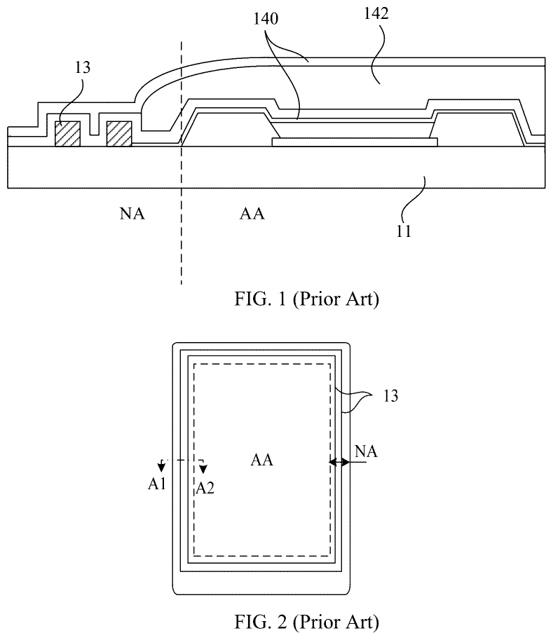

FIG. 1 is a cross-sectional view of a display panel in related technologies. As shown in FIG. 1, the display panel has a display area AA and an edge area NA surrounding the display area AA. The edge area NA is provided with a dam 13 to form a stop structure to prevent an organic encapsulation layer 142 from overflowing. Two inorganic encapsulation layers 140 are provided to wrap the organic encapsulation layer 142 and are contacted with the dam 13.

As mentioned in the background part, the reliability of the display panel shown in FIG. 1 is relatively low.

After a deep research by the inventor, it is found that the dam 13 in the related technologies is usually an organic material layer. In this case, a contact surface between the dam 13 and the inorganic encapsulation layer 140 forms contact between an organic material and an inorganic material, resulting in poor adhesion at the interface. In a high-temperature and high-humidity environment, film layers are prone to be separated at such interface. Meanwhile, as an encapsulation edge includes an interface between the dam 13 and a layer of inorganic encapsulation layer 140 and an interface between two inorganic encapsulation layers 140, multiple interfaces further increase a probability of separation at the interfaces between film layers. After separation at the interface between adjacent film layers, a water-oxygen infiltrating path is formed, resulting in lower reliability of a product.

In view of this, embodiments of the present disclosure provide a display panel and a method for manufacturing the display panel, and a display module. An inorganic encapsulation layer 140, located farther away from the substrate 11 of two inorganic encapsulation layers 140, is configured to directly contact with a dam 13, to reduce a quantity of interfaces at an encapsulation edge. Meanwhile, the encapsulation edge is thinner, thereby reducing a probability of separation between film layers, and improving reliability of the display panel.

A clear and complete description of the technical solution in the embodiments of the present disclosure will be provided with reference to the accompanying drawings. Obviously, the described embodiments are only a part of the embodiments of the present disclosure, not all of them. Based on the embodiments in the present disclosure, all other embodiments obtained by those skilled in the art without creative labor fall within the scope of protection of the present disclosure.

In the accompanying drawings, for clarity of illustration, sizes of the layers and areas may be exaggerated. It can be understood that when a structure is referred to be “above or below” another structure, the structure may be directly above or below another structure, or there may further be an intermediate structure in the structure and another structure. A same reference numerals indicate a same structure. The structure mentioned therein includes any one of a film layer, an element, a device, a member, and a component.

When a structure is referred to be “connected” to another structure, the structure may be directly connected to another structure, or indirectly connected to another structure by one or more intermediate structures placed between the two structures.

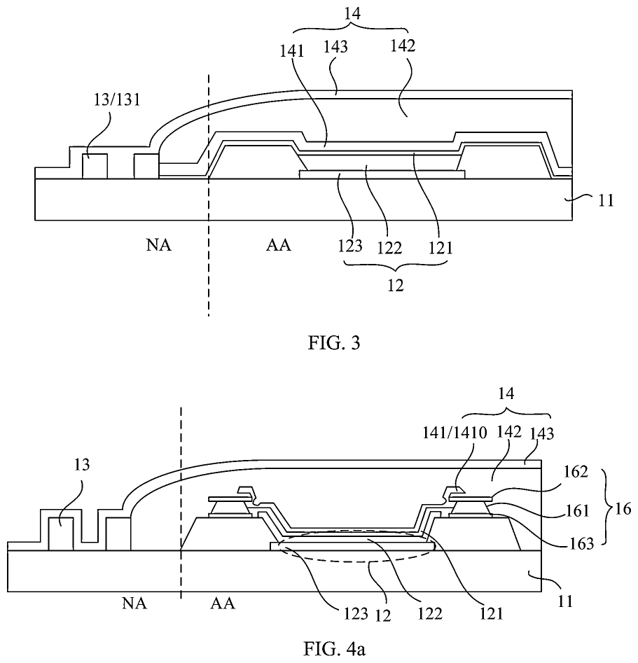

FIG. 2 is a top view of a display panel according to an embodiment of the present disclosure. FIG. 3 is a cross-sectional view of the display panel along line A1-A2 shown in FIG. 2. As shown in FIG. 2 and FIG. 3, the display panel has a display area AA and an edge area NA surrounding the display area AA.

The display panel includes a substrate 11, a plurality of light-emitting devices 12, a dam 13, and an encapsulation structure 14

The substrate 11 may be a base substrate or an array substrate. The base substrate may be a flexible base substrate, such as a polyimide film, or may be a hard substrate, such as a glass substrate or a silicon substrate. The array substrate is a substrate including a base substrate and a pixel circuit formed on the base substrate. The pixel circuit and the light-emitting device 12 are connected in one-to-one correspondence to drive the light-emitting device 12 to emit light.

The light-emitting device 12 is disposed on the substrate 11 and is located in the display area AA. The light-emitting device 12 is, for example, an organic light-emitting diode. The light-emitting device 12 includes a first electrode 121, a light-emitting unit 122, and a second electrode 123. The first electrode 121, the light-emitting unit 122, and the second electrode 123 are sequentially stacked in a direction gradually closing to the substrate 11. Exemplarily, the first electrode 121 is a cathode, and the second electrode 123 is an anode.

The dam 13 is disposed on the substrate 11 and is located in the edge area NA. The dam 13 surrounds the display area AA. The dam 13 may be of a single film layer structure, or may be of a multi-layers stacked structure.

The encapsulation structure 14 is stacked on a side, facing away from the substrate 11, of the dam 13 and the plurality of light-emitting devices 12. The encapsulation structure 14 is a thin film encapsulation structure, including a first inorganic encapsulation layer 141 and a second inorganic encapsulation layer 143. An orthographic projection of the first inorganic encapsulation layer 141 on the substrate 11 is within an orthographic projection of the second inorganic encapsulation layer 143 on the substrate 11. The first inorganic encapsulation layer 141 is located in an area defined by the dam 13, that is, the first inorganic encapsulation layer 141 is retracted in the second inorganic encapsulation layer 143. The second inorganic encapsulation layer 143 extends from the display area AA to the edge area NA to directly contact with the dam 13. Direct contact means that there is no other structure between the second inorganic encapsulation layer 143 and the dam 13.

In an embodiment, the encapsulation structure 14 further includes an organic encapsulation layer 142 stacked on a side, facing away from the substrate 11, of the first inorganic encapsulation layer 141. An orthographic projection of the organic encapsulation layer 142 on the substrate 11 covers orthographic projections of the plurality of light-emitting devices 12 on the substrate 11, and an edge of the organic encapsulation layer 142 ends at a side, close to the display area AA, of the dam 13. That is, the dam 13 plays a role in stopping the organic encapsulation layer 142, thereby preventing an organic encapsulation material from overflowing outside the substrate 11 during a preparation process of the organic encapsulation layer 142.

According to the display panel provided in the embodiment, a second inorganic encapsulation layer 143 is configured to directly contact with a dam 13, so that a quantity of interfaces at an encapsulation edge is reduced. Meanwhile, the encapsulation edge is thinner, thereby reducing a probability of separation between film layers, and improving reliability of the display panel.

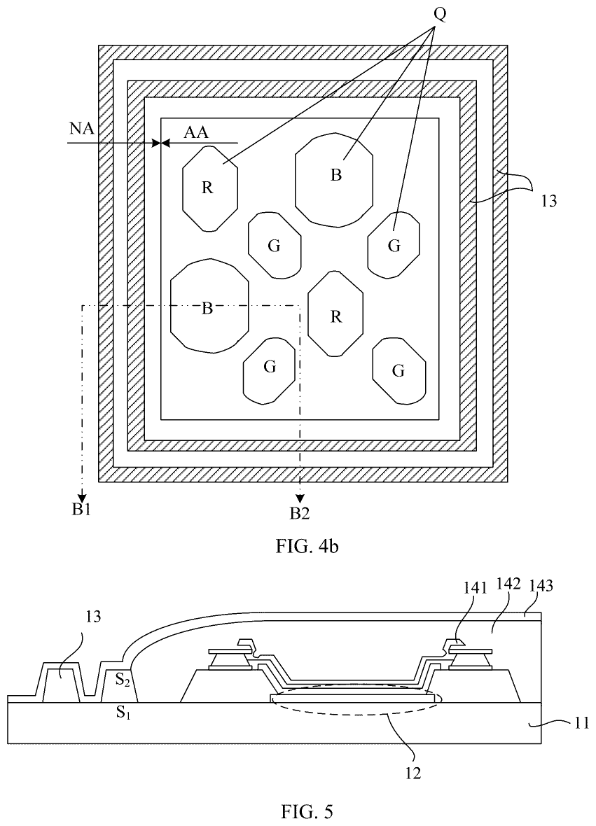

FIG. 4a is a cross-sectional view of a display panel according to another embodiment of the present disclosure. FIG. 4b is a top view of the display panel shown in FIG. 4a. The structure of the cross-section shown in FIG. 4a corresponds to a cross-section line B1-B2 shown in FIG. 4b, and FIG. 4b shows only part of film layers in the display panel shown in FIG. 4a. With reference to FIG. 4a and FIG. 4b, the display panel provided by the embodiment differs from the display panel shown in FIG. 3 in that the first inorganic encapsulation layer 141 includes a plurality of inorganic encapsulation portions 1410. The inorganic encapsulation portion 1410 and the light-emitting device 12 are in one-to-one correspondence, and an orthographic projection of the inorganic encapsulation portion 1410 on the substrate 11 covers an orthographic projection of the light-emitting device 12 on the substrate 11.

In the present embodiment, the display panel further includes an isolation structure 16 stacked on a side of the substrate 11. The isolation structure 16 is defined with a plurality of isolation openings Q, and the light-emitting device 12 is located in the isolation opening Q. In a direction from the display area AA to the edge area NA, a cross-sectional shape of the isolation structure 16 is an inverted trapezoid or similar to an I-shaped shape, so that the isolation structure 16 may isolate a film layer evaporated on a side, facing away from the substrate, of the isolation structure 16, such as a light-emitting layer and a second electrode layer, to obtain the light-emitting unit 122 and the first electrode 121, respectively.

Exemplarily, the inorganic encapsulation portion 1410 is located on a side, facing away from the substrate 11, of the light-emitting device 12, and covers a side wall, facing the isolation opening, of the isolation structure 16. Furthermore, in an embodiment, the inorganic encapsulation portion 1410 further extends to a side, facing away from the substrate 11, of the isolation structure 16.

Exemplarily, the isolation structure 16 includes a first sub-portion 161 and a second sub-portion 162. The first sub-portion 161 is located on a side, close to the substrate 11, of the second sub-portion 162, and an orthographic projection of the first sub-portion 161 on the substrate 11 is within an orthographic projection of the second sub-portion 162 on the substrate 11. Thus, the first sub-portion 161 and the second sub-portion 162 cooperate to form the isolation structure 16 with an inverted trapezoidal cross-section.

A material of the first sub-portion 161 is a conductive material, and the light-emitting device 12 includes a first electrode 121. The first electrode 121 is contacted with the first sub-portion 161.

The first sub-portion 161 may be an independent film layer, that is, there is no physical interface inside the first sub-portion 161. The first sub-portion 161 may alternatively be formed by stacking at least two film layers. For example, materials of the two film layers may be molybdenum and aluminum, respectively. A conductive film layer composed of molybdenum is located between the substrate and a conductive film layer composed of aluminum. The second sub-portion 162 may be a non-conductive material film layer, such as an inorganic film layer. Alternatively, the second sub-portion 162 may also be a conductive film layer, and a material of the second sub-portion 162 may be, for example, titanium.

The isolation structure 16 may further include a third sub-portion 163. The third sub-portion 163 is located on a side, close to the substrate 11, of the first sub-portion 161, and the orthographic projection of the first sub-portion 161 on the substrate 11 is within an orthographic projection of the third sub-portion 163 on the substrate 11. Exemplarily, the first sub-portion 161 is an independent film layer including aluminum, and the third sub-portion 163 is an independent film layer including molybdenum. An orthographic projection of the aluminum film layer on the substrate 11 is within an orthographic projection of the molybdenum film layer on the substrate 11. Thus, the second sub-portion 162, the first sub-portion 161, and the third sub-portion 163 cooperate to form the isolation structure 16 with an I-shaped cross-section. Related content of an isolation structure and an encapsulation layer are recorded in patent applications including No. PCT/CN2023/134518, No. 202311499823.9, No. 202310707209.0, No. 202311346196.5, No. 202310692671.8, and No. 202311091555.7. The isolation structure and the encapsulation layer of the present disclosure may be further referred to the foregoing patent applications.

According to the display panel provided by the embodiment, due to the existence of the isolation structure 16, a conventional process of manufacturing a display panel includes a process of patterning performed on the first inorganic encapsulation layer 141. Therefore, in the present embodiment, an orthographic projection of the first inorganic encapsulation layer 141 on the substrate is located within an orthographic projection of the second inorganic encapsulation layer 143 on the substrate and no additional process needs to be added, thereby improving applicability.

FIG. 5 is a cross-sectional view of a display panel according to still another embodiment of the present disclosure. As shown in FIG. 5, the display panel provided in the embodiment differs from the display panel provided by any one of the above embodiments in that in the present embodiment, taking the display panel shown in FIG. 5 as an example, the dam 13 includes a first surface S1 close to the substrate 11, a second surface S2 facing away from the substrate 11, and a side surface connecting the first surface S1 and the second surface S2. An orthographic projection of the first surface S1 on the substrate 11 is within an orthographic projection of the second surface S2 on the substrate 11. An included angle between the side surface and the first surface S1 is an acute angle. Exemplarily, the acute angle is greater than or equal to 30° and less than or equal to 75°. Exemplarily, in a direction from the display area AA to the edge area NA, a cross-sectional shape of the dam 13 is a positive trapezoid.

According to the display panel provided by the present embodiment, the second inorganic encapsulation layer 143 may be ensured to be continuous and uninterrupted at the dam 13, thereby extending an encapsulation path and improving encapsulation effect.

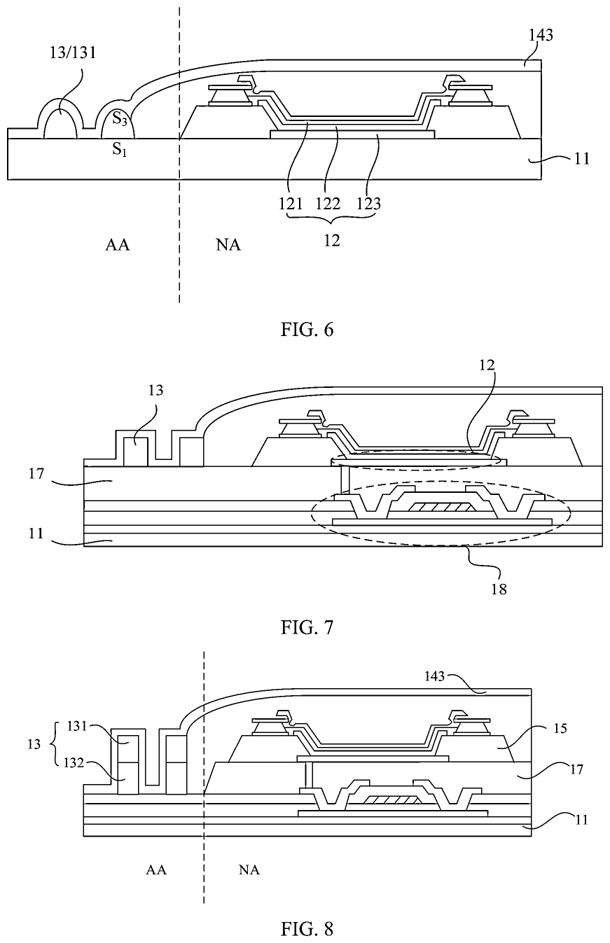

FIG. 6 is a cross-sectional view of a display panel according to yet still another embodiment of the present disclosure. As shown in FIG. 6, the display panel provided by the embodiment differs from the display panel provided by any one of the above embodiments in that in the present embodiment, taking the display panel shown in FIG. 5 as an example, the second surface S2 is transited to the side surface of the dam 13 smoothly. That is, a sharp corner is not formed at a joint between the second surface S2 and the side surface, so that the second surface S2 and the side surface are joined into a complete smooth surface, and the complete smooth surface is referred to as a third surface S3, as shown in FIG. 6. In this case, the dam 13 includes the first surface S1 close to the substrate 11 and the third surface S3 other than the first surface S1. The third surface S3 is a smooth surface. Exemplarily, in a direction from the display area AA to the edge area NA, a cross-section of the dam 13 is arc-shaped.

According to the display panel provided by the present embodiment, a dam 13 includes a first surface S1 close to the substrate 11 and a third surface S3 other than the first surface S1, and the third surface S3 is a smooth surface, so that the second inorganic encapsulation layer 143 ensure may be ensured to be continuous and uninterrupted at the dam 13, thereby extending the encapsulation path and improving the encapsulation effect.

FIG. 7 is a cross-sectional view of a display panel according to yet still another embodiment of the present disclosure. As shown in FIG. 7, the display panel provided by the present embodiment differs from the display panel provided by any one of the above embodiments in that in the present embodiment, taking the display panel shown in FIG. 7 as an example, the display panel further includes a second insulating layer 17 located between the substrate 11 and the light-emitting device 12. The first surface S1, close to the substrate 11, of the dam 13 is contacted with the second insulating layer 17, and a material of the second insulating layer 17 is any one of an inorganic material and an organic material. Preferably, the material of the second insulating layer 17 is an inorganic material, so that a contact surface between the dam 13 and the second insulating layer 17 form contact between an inorganic material and an inorganic material, thereby improving an interface bonding force and further improving the encapsulation effect.

In an embodiment, the display panel may further include a pixel circuit 18 located between the second insulating layer 17 and the substrate 11. The pixel circuit 18 is electrically connected to the light-emitting device 12 through a conductive through hole penetrating through the second insulating layer 17. The pixel circuit 18 may be a 7T1C pixel circuit, an 8T1C pixel circuit, and the like.

FIG. 8 is a cross-sectional view of a display panel according to yet still another embodiment of the present disclosure. As shown in FIG. 8, the display panel provided by the present embodiment differs from the display panel provided by any one of the above embodiments in that in the embodiment, taking the display panel shown in FIG. 8 as an example, the dam 13 includes a top film layer 131, and a material of at least part of the top film layer is an inorganic material. For example, the material of the whole top film layer 131 is an inorganic material. For another example, in a direction from the display area AA to the edge area NA, the top film layer 131 includes inorganic material portions and organic material portions alternately disposed. The second inorganic encapsulation layer 143 is contacted with the top film layer 131 of the dam 13.

According to the display panel provided by the embodiment, a contact surface between the dam 13 and the encapsulation structure 14 is actually a contact surface between the top film layer 131 and the second inorganic encapsulation layer 143. Furthermore, as the material of the top film layer 131 is configured to be the inorganic material, the contact between the top film layer 131 and the second inorganic encapsulation layer 143 is contact between an inorganic material and an inorganic material, thereby improving the interface bonding force, reducing the probability of separation of the interface between film layers in a high-temperature and high-humidity environment, and further improving the reliability of the display panel.

In an embodiment, the display panel may further include a first insulating layer 15 stacked on the substrate 11 and located in the display area AA. The first insulating layer 15 is defined with a plurality of pixel openings, and the light-emitting device 12 is located in the pixel opening. The top film layer 131 and the first insulating layer 15 are disposed in a same layer.

The first insulating layer 15 is, for example, a pixel defining layer, and a material of the pixel defining layer is the same as the material of the top film layer 131. In this case, the pixel definition layer and the top film layer 131 may be synchronously prepared, thereby simplifying the preparation process.

In an embodiment, the dam 13 may further include a pad layer 132 stacked on a side, close to the substrate 11, of the top film layer 131. The pad layer 132 may be an independent film layer, that is, there is no physical interface inside the pad layer 132. The pad layer 132 may alternatively be a multi-layer stacked structure. A material of the pad layer 132 includes at least one of an organic material and an inorganic material. The pad layer 132 may be configured as a height adjustment layer of the dam 13, and a desired height of the dam 132 is obtained by reasonably configuring a height of the pad layer 132, thereby ensuring a stop effect of the dam 132.

In an embodiment, the display panel may further include a second insulating layer 17 located between the substrate 11 and the light-emitting device 12. The second insulating layer 17 is located in the display area AA, and the second insulating layer 17 and the pad layer 132 are disposed in a same layer. Thus, increase of a thickness of the display panel caused by introduction of the pad layer 132 may be avoided, beneficial to product thinning. Exemplarily, a material of the second insulating layer 17 is the same as a material of the pad layer 132. In this case, the second insulating layer 17 and the pad layer 132 may be prepared synchronously, thereby simplifying the preparation process.

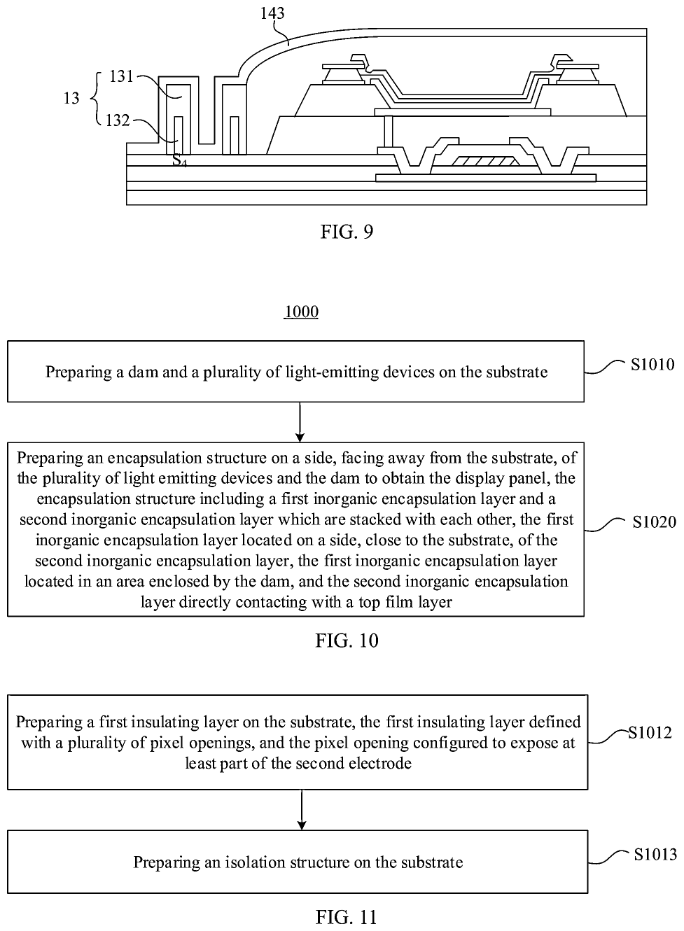

FIG. 9 is a cross-sectional view of a display panel according to yet still another embodiment of the present disclosure. As shown in FIG. 9, the display panel provided by the present embodiment differs from the display panel shown in FIG. 8 in that the pad layer 132 includes a fourth surface S4 close to the substrate 11, and the top film layer 131 covers a surface of the pad layer 132 other than the fourth surface S4. In this case, a contact surface between the dam 13 and the second inorganic encapsulation layer 143 is only a contact surface between the top film layer 131 and the second inorganic encapsulation layer 143, and even if the material of the pad layer 132 is an organic material, a bonding force of an interface between the dam 13 and the second inorganic encapsulation layer 143 may not be adversely affected by the pad layer 132.

The present disclosure further provides another display panel. As shown in FIG. 4a and FIG. 4b, the display panel has a display area AA and an edge area NA surrounding the display area AA. The display panel includes a substrate 11, a plurality of light-emitting devices 12, a dam 13 and an encapsulation structure 14. The light-emitting device 12 is disposed on the substrate 11 and is located in the display area AA. The dam 13 is disposed on the substrate 11 and is located in the edge area NA. The dam 13 surrounds the light-emitting device 12. The encapsulation structure 14 is stacked on a side, facing away from the substrate 11, of the dam 13 and the plurality of light-emitting devices 12. The encapsulation structure 14 includes a first inorganic encapsulation layer 141 and a second inorganic encapsulation layer 143 which are stacked with each other, and the first inorganic encapsulation layer 141 is located on a side, close to the substrate 11, of the second inorganic encapsulation layer 143. In a direction from the edge area to the display area, the first inorganic encapsulation layer 141 is retracted in the second inorganic encapsulation layer 143. That is, an orthographic projection of the first inorganic encapsulation layer 141 on the substrate 11 is within an orthographic projection of the second inorganic encapsulation layer 143 on the substrate 11, and there is a distance between edges of the orthographic projection of the first inorganic encapsulation layer 141 on the substrate 11 and edges of the orthographic projection of the second inorganic encapsulation layer 143 on the substrate 11. An area of the orthographic projection area of the first inorganic encapsulation layer 141 on the substrate 11 is less than an area of the orthographic projection area of the second inorganic encapsulation layer 143 on the substrate 11. In this case, the first inorganic encapsulation layer 141 is located in an area defined by the dam 13, and the orthographic projection of the second inorganic encapsulation layer 143 on the substrate 11 covers an orthographic projection of the dam 13 on the substrate 11.

In an embodiment, the display panel further includes an isolation structure 16, located on a same side of the substrate 11 as the light-emitting device 12. The isolation structure 16 is defined with a plurality of isolation openings, and the light-emitting device 12 is located in the isolation opening.

In an embodiment, the first inorganic encapsulation layer 141 includes a plurality of inorganic encapsulation portions 1410, and the inorganic encapsulation portions 1410 and the light-emitting devices 12 are in one-to-one correspondence.

In an embodiment, the inorganic encapsulation portion 1410 is located on a side, facing away from the substrate 11, of the light-emitting device 12 and covers a side wall, facing the isolation opening, of the isolation structure 16.

In an embodiment, the inorganic encapsulation portion 1410 further extends to a side, facing away from the substrate 11, of the isolation structure 16.

In an embodiment, the display panel further includes an organic encapsulation layer 142 located between the first inorganic encapsulation layer 141 and the second inorganic encapsulation layer 143.

In an embodiment, an orthographic projection of the organic encapsulation layer 142 on the substrate 11 covers orthographic projections of the plurality of light-emitting devices 12 on the substrate 11.

In an embodiment, the display panel further includes a dam 13 located in the edge area NA. The dam 13 is located between the second inorganic encapsulation layer 143 and the substrate 11 and is directly contacted with the second inorganic encapsulation layer 143.

In an embodiment, the dam 13 surrounds the display area AA, and the first inorganic encapsulation layer 141 is located in an area defined by the dam 13.

It should be noted that, for technical details not described in the embodiment, related descriptions of the embodiments shown in FIG. 4a and FIG. 4b may be referred to, and details are not described herein again.

The present disclosure further provides a method for manufacturing a display panel. FIG. 10 is a flowchart of a method for manufacturing a display panel according to an embodiment of the present disclosure. As shown in FIG. 10, the method for manufacturing the display panel 1000 includes the following steps.

Step S1010: preparing a dam and a plurality of light-emitting devices on the substrate. The dam surrounds the plurality of light-emitting devices, and the dam includes a top film layer. A material of the top film layer is an inorganic material.

Specifically, referring to any one of the display panels shown in FIGS. 1 to 9, a second electrode layer, a light-emitting layer and a first electrode layer are sequentially prepared on the substrate 11 to form the plurality of light-emitting devices. The second electrode layer includes a plurality of second electrodes 123 disposed with intervals, and the plurality of second electrodes 123, the light-emitting layer, and the first electrode layer which are stacked with each other constitute the plurality of light-emitting device 12.

FIG. 11 is a flowchart of a method for manufacturing a display panel according to another embodiment of the present disclosure. In an embodiment, after preparing a second electrode layer, and before preparing the light-emitting layer, the method further includes the following steps.

Step S1012: preparing a first insulating layer on the substrate, the first insulating layer defined with a plurality of pixel openings, and the pixel opening configured to expose at least part of the second electrode.

In an embodiment, after preparing the first insulating layer and before preparing the light-emitting layer, the method further includes the following steps.

Step S1013: preparing an isolation structure on the substrate.

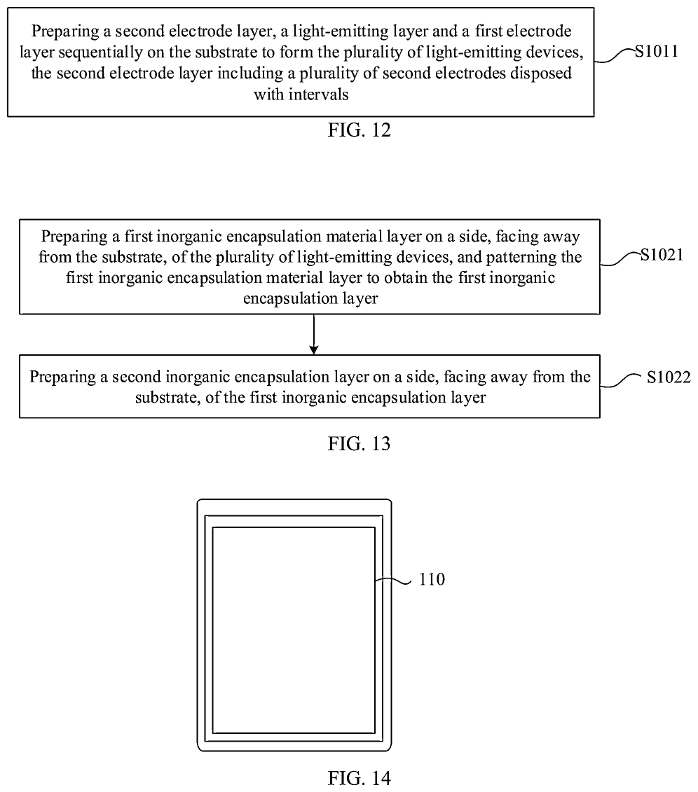

FIG. 12 is a flowchart of a method for manufacturing a display panel according to still another embodiment of the present disclosure. In an embodiment, as shown in FIG. 12, the preparing a plurality of light-emitting devices on a substrate further includes the following steps.

Step S1011: preparing a second electrode layer, a light-emitting layer and a first electrode layer sequentially on the substrate to form the plurality of light-emitting devices, the second electrode layer including a plurality of second electrodes disposed with intervals.

Specifically, following the above example, after the first insulating layer 15 is prepared and before the light-emitting layer is prepared, the isolation structure 16 is prepared on a side, facing away from the substrate 11, of the first insulating layer 15. The isolation structure 16 is defined with a plurality of isolation openings, and an orthographic projection of the isolation opening on the substrate 11 covers an orthographic projection of the pixel opening on the substrate 11. Subsequently, the light-emitting layer and the first electrode layer are sequentially evaporated in the pixel opening. The light-emitting layer is disconnected at an edge of the isolation structure 16 to form a light-emitting unit 122. The first electrode layer is disconnected at the edge of the isolation structure 16, to form the first electrode 121. The second electrode 123, the light-emitting unit 122, and the first electrode 121 stacked in a same pixel opening constitute the light-emitting device 12.

Exemplarily, while the first insulating layer 15 is prepared, the dam 13 is also prepared. That is, the dam 13 and the first insulating layer 15 are synchronously prepared.

Step S1020: preparing an encapsulation structure on a side, facing away from the substrate, of the plurality of light emitting devices and the dam to obtain the display panel, the encapsulation structure including a first inorganic encapsulation layer and a second inorganic encapsulation layer which are stacked with each other, the first inorganic encapsulation layer located on a side, close to the substrate, of the second inorganic encapsulation layer, the first inorganic encapsulation layer located in an area defined by the dam, and the second inorganic encapsulation layer directly contacting with a top film layer.

For example, the first inorganic encapsulation layer 141, an organic encapsulation layer 142, and the second inorganic encapsulation layer 143 are sequentially prepared on a side, facing away from the substrate 11, of the plurality of light-emitting devices 12 and the dam 13. The first inorganic encapsulation layer 141 is located in an area defined by the dam 13, and for example, the first inorganic encapsulation layer 141 is located in the display area AA. The organic encapsulation layer 142 covers the first inorganic encapsulation layer 141 in the display area AA and ends at a side, close to the display area AA, of the dam 13. The second inorganic encapsulation layer 143 covers the organic encapsulation layer 142 and is contacted with the dam 13 in the edge area NA.

FIG. 13 is a flowchart of a method for manufacturing a display panel according to yet still another embodiment of the present disclosure. In an embodiment, as shown in FIG. 13, Step S1020 specifically includes the following steps.

Step S1021: preparing a first inorganic encapsulation material layer on a side, facing away from the substrate, of the plurality of light-emitting devices, and patterning the first inorganic encapsulation material layer to obtain the first inorganic encapsulation layer.

Step S1022: preparing a second inorganic encapsulation layer on a side, facing away from the substrate, of the first inorganic encapsulation layer.

First, the first inorganic encapsulation material layer is prepared on the side, facing away from the substrate 11, of the light-emitting device 12, and then the first inorganic encapsulation material layer is patterned to obtain the first inorganic encapsulation layer 141. Secondly, the second inorganic encapsulation layer 143 is prepared on the side, facing away from the substrate 11, of the first inorganic encapsulation layer 141. An orthographic projection of the second inorganic encapsulation layer 143 on the substrate 11 covers an orthographic projection of the first inorganic encapsulation layer 141 on the substrate 11. In the present embodiment, the first inorganic encapsulation layer includes a plurality of inorganic encapsulation portions 1410. The inorganic encapsulation portions 1410 and the light-emitting devices 12 are in one-to-one correspondence. Exemplarily, the inorganic encapsulation portion 1410 is located on a side, facing away from the substrate 11, of the light-emitting device 12 and covers a side wall, facing the isolation opening, of the isolation structure 16. In a further embodiment, the inorganic encapsulation portion 1410 further extends to a side, facing away from the substrate 11, of the isolation structure 16.

According to the manufacturing method of the display panel provided by the present embodiment, a contact surface between the dam 13 and the encapsulation structure 14 is actually a contact surface between the top film layer 131 and the second inorganic encapsulation layer 143. A material of the top film layer 131 is an inorganic material, so that the contact between the top film layer 131 and the second inorganic encapsulation layer 143 is contact between an inorganic material and an inorganic material, thereby improving an interface bonding force, reducing a probability of separation of interface between film layers in a high-temperature and high-humidity environment, and further improving reliability of the display panel.

The present disclosure further provides a display module, including the display panel provided by any one of the foregoing embodiments.

The present disclosure further provides a display apparatus. FIG. 14 is a schematic structural diagram of a display apparatus according to an embodiment of the present disclosure. As shown in FIG. 14, the display apparatus includes the display module 110 according to any one of the foregoing embodiments.

The display apparatus is a product having an image display function. Exemplarily, the display apparatus may be configured to display a static image, such as a picture or a photo. The display apparatus may alternatively be used to display a dynamic image, such as a video.

The display apparatus may be a notebook computer, a mobile phone, a handheld or portable computer, a camera, a camcorder, a vehicle-mounted intelligent central control screen, a calculator, a smart watch, a GPS navigator, an electronic photo, an electronic billboard or indicator, a projector, and the like.

In addition, the display apparatus may further have functions such as photographing, video recording, fingerprint recognition, face recognition and so on. Correspondingly, the display apparatus further includes at least one functional module configured to implement the foregoing functions, for example, an under-screen camera, an under-screen fingerprint recognition sensor, and so on.

The above describes the basic principles of the present disclosure with reference to specific embodiments. However, it should be pointed out that the advantages, benefits, effects, and the like mentioned in the present disclosure are only examples and not limitations, and cannot be considered as essential for each embodiment of the present disclosure. In addition, the specific details disclosed above are only for the purpose of providing examples and facilitating understanding, and are not limited. The above details do not limit the necessity for the present disclosure to use the above specific details for implementation.

For the purpose of illustration and description, the above description has been provided. Furthermore, the description is not intended to limit the embodiments of the present disclosure to the form disclosed herein. Although multiple exemplary aspects and embodiments have been discussed above, those skilled in the art will recognize certain variations, modifications, alterations, additions, and sub-combinations thereof.

What is claimed is:

1. A display panel, having a display area and an edge area surrounding the display area, wherein the display panel comprises:
a substrate;
a plurality of light-emitting devices, disposed on the substrate and located in the display area;
a dam, disposed on the substrate and located in the edge area, wherein the dam is disposed surrounding the display area; and
an encapsulation structure, stacked on a side, facing away from the substrate, of the dam and the plurality of light-emitting devices, comprising a first inorganic encapsulation layer and a second inorganic encapsulation layer which are stacked with each other, the first inorganic encapsulation layer located on a side, close to the substrate, of the second inorganic encapsulation layer; and the second inorganic encapsulation layer extending from the display area to the edge area to directly contact with the dam.

2. The display panel according to claim 1, wherein the dam comprises a top film layer, the top film layer is contacted with the second inorganic encapsulation layer, and a material of at least part of the top film layer comprises an inorganic material.

3. The display panel according to claim 2, further comprising a first insulating layer disposed on the substrate and located in the display area, wherein the first insulating layer is defined with a plurality of pixel openings, the light-emitting device is located in the pixel opening, and the top film layer and the first insulating layer are disposed in a same layer; and
the first insulating layer and the top film layer comprise a same material.

4. The display panel according to claim 1, further comprising an isolation structure located on a side of the substrate, wherein the isolation structure is defined with a plurality of isolation openings, and the light-emitting device is located in the isolation opening;
the isolation structure comprises a first sub-portion and a second sub-portion, the first sub-portion is located on a side, close to the substrate, of the second sub-portion, and an orthographic projection of the first sub-portion on the substrate is within an orthographic projection of the second sub-portion on the substrate;
a material of the first sub-portion is a conductive material, the light-emitting device comprises a first electrode, and the first electrode is contacted with the first sub-portion;
the light-emitting device further comprises a light-emitting material layer and a second electrode, and the second electrode, the light-emitting material layer, and the first electrode are sequentially stacked in a direction from the substrate to the light-emitting device;
the isolation structure further comprises a third sub-portion, the third sub-portion is located on a side, close to the substrate, of the first sub-portion, and the orthographic projection of the first sub-portion on the substrate is within an orthographic projection of the third sub-portion on the substrate; and
the display panel further comprises a first insulating layer, the first insulating layer is disposed on the substrate and located in the display area; the first insulating layer is defined with a plurality of pixel openings, the plurality of pixel openings are in communication with the plurality of isolation openings respectively, and the light-emitting device is further located in the pixel opening.

5. The display panel according to claim 1, wherein the first inorganic encapsulation layer is located in an area defined by the dam;
the first inorganic encapsulation layer comprises a plurality of inorganic encapsulation portions disposed with intervals, the plurality of inorganic encapsulation portions and the plurality of light-emitting devices are in one-to-one correspondence, and an orthographic projection of the inorganic encapsulation portion on the substrate covers an orthographic projection of the light-emitting device on the substrate;
an orthographic projection of the first inorganic encapsulation layer is within an orthographic projection of the second inorganic encapsulation layer on the substrate; and
an orthographic projection of the first inorganic encapsulation layer on the substrate is located within an orthographic projection of the second inorganic encapsulation layer on the substrate.

6. The display panel according to claim 5, wherein the display panel further comprises an isolation structure stacked on a side of the substrate, the isolation structure is defined with a plurality of isolation openings, the light-emitting device is located in the isolation opening; and the inorganic encapsulation portion is located on a side, facing away from the substrate, of the light-emitting device and covers a side wall, facing the isolation opening, of the isolation structure; and
the inorganic encapsulation portion further extends to a side, facing away from the substrate, of the isolation structure.

7. The display panel according to claim 1, wherein the encapsulation structure further comprises an organic encapsulation layer disposed between the first inorganic encapsulation layer and the second inorganic encapsulation layer, and the organic encapsulation layer ends at a side, close to the display area, of the dam; and
an orthographic projection of the organic encapsulation layer on the substrate covers orthographic projections of the plurality of light-emitting devices on the substrate.

8. The display panel according to claim 1, wherein the dam comprises a first surface close to the substrate and a second surface facing away from the substrate, and an orthographic projection of the second surface on the substrate is within an orthographic projection of the first surface on the substrate.

9. The display panel according to claim 1, wherein the dam comprises a first surface close to the substrate and a third surface other than the first surface, and the third surface is a smooth surface; and
in a direction from the display area to the edge area, a cross-section of the dam is arc-shaped.

10. The display panel according to claim 1, further comprising a second insulating layer located between the substrate and the plurality of light-emitting devices, a first surface, close to the substrate, of the dam is contacted with the second insulating layer, and a material of the second insulating layer is any one of an inorganic material or an organic material.

11. The display panel according to claim 2, wherein the dam further comprises a pad layer located on a side, close to the substrate, of the top film layer.

12. The display panel according to claim 11, wherein the display panel further comprises a second insulating layer located between the substrate and the light-emitting device, the second insulating layer is located in the display area, and the second insulating layer and the pad layer are disposed in a same layer;
the second insulating layer and the pad layer comprise a same material;
the material of the pad layer comprises at least one of an organic material and an inorganic material; and
the top film layer covers a side surface and a surface facing away from the substrate of the pad layer.

13. A display panel, having a display area and an edge area surrounding the display area, wherein the display panel comprises:
a substrate;
a plurality of light-emitting devices, disposed on the substrate and located in the display area; and
an encapsulation structure, stacked on a side, facing away from the substrate, of the plurality of light-emitting devices, comprising a first inorganic encapsulation layer and a second inorganic encapsulation layer which are stacked with each other, the first inorganic encapsulation layer located on a side, close to the substrate, of the second inorganic encapsulation layer, and an orthographic projection of the first inorganic encapsulation layer on the substrate located within an orthographic projection of the second inorganic encapsulation layer on the substrate.

14. The display panel according to claim 13, further comprising an isolation structure, located on a same side of the substrate as the plurality of light-emitting devices; wherein the isolation structure is defined with a plurality of isolation openings, and the light-emitting device is located in the isolation opening;
the first inorganic encapsulation layer comprises a plurality of inorganic encapsulation portions, and the inorganic encapsulation portions and the light-emitting devices are in one-to-one correspondence;
the inorganic encapsulation portion is located on a side, facing away from the substrate, of the light-emitting device and covers a side wall, facing the isolation opening, of the isolation structure;
the inorganic encapsulation portion further extends to a side, facing away from the substrate, of the isolation structure;
the display panel further comprises an organic encapsulation layer located between the first inorganic encapsulation layer and the second inorganic encapsulation layer; and
an orthographic projection of the organic encapsulation layer on the substrate covers orthographic projections of the plurality of light-emitting devices on the substrate.

15. The display panel according to claim 13, further comprising a dam located in the edge area, wherein the dam is located between the second inorganic encapsulation layer and the substrate and is directly contacted with the second inorganic encapsulation layer; and
the dam surrounds the display area, and the first inorganic encapsulation layer is located in an area defined by the dam.

16. A method for manufacturing a display panel, comprising:
preparing a dam and a plurality of light-emitting devices on a substrate, the dam surrounding the plurality of light-emitting devices; and
preparing an encapsulation structure on a side, facing away from the substrate, of the plurality of light-emitting devices and the dam, to obtain the display panel, the encapsulation structure comprising a first inorganic encapsulation layer and a second inorganic encapsulation layer which are stacked with each other, the first inorganic encapsulation layer located on a side, away from the substrate, of the second inorganic encapsulation layer, and the second inorganic encapsulation layer directly contacting with the dam.

17. The method for manufacturing the display panel according to claim 16, wherein the preparing an encapsulation structure on a side, facing away from the substrate, of the plurality of light-emitting devices and the dam comprises:
preparing a first inorganic encapsulation material layer on the side, facing away from the substrate, of the plurality of light-emitting devices, and patterning the first inorganic encapsulation material layer to obtain the first inorganic encapsulation layer; and
preparing the second inorganic encapsulation layer on a side, facing away from the substrate, of the first inorganic encapsulation layer;
wherein the dam comprises a top film layer; and
the preparing a plurality of light-emitting devices on a substrate comprises:
preparing a second electrode layer, a light-emitting layer and a first electrode layer sequentially on the substrate to form the plurality of light-emitting devices, the second electrode layer comprising a plurality of second electrodes disposed with intervals.

18. The method for manufacturing the display panel according to claim 17, after the light-emitting layer is prepared and before preparing the second electrode layer, further comprising:
synchronously preparing a first insulating layer and the top film layer on the substrate, the first insulating layer defined with a plurality of pixel openings, and the pixel opening configured to expose at least part of the second electrode.

19. The method for manufacturing the display panel according to claim 17, further comprising: preparing an isolation structure on the substrate, the isolation structure defined with a plurality of isolation openings, and the light-emitting device located in the isolation opening.

20. A display module, comprising the display panel according to claim 1.
